(19) United States
(12) Patent Application Publication
(10) Pub. No.: US 2008/0137470 A1
(43) Pub. Date: Jun. 12, 2008

(54) Memory with data clock receiver and command/address clock receiver

(76) Inventors: Josef Schnell, Charlotte, VT (US); Farrukh Aquil, South Burlington, VT (US); Harald Streif, Davis, CA (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/635,164

(22) Filed: Dec. 7, 2006

(51) Int. Cl. G11C 8/00

(52) U.S. Cl. 365/233.1

(57) ABSTRACT

One embodiment provides a memory device including a memory bank, a first receiver, and a second receiver. The memory bank includes memory cells. The first receiver is configured to receive a clock signal and provide a data clock signal based on the clock signal. The second receiver is configured to receive the clock signal and provide a command/address clock signal based on the clock signal. The first receiver provides the data clock signal to output read data from the memory cells. The second receiver provides the command/address clock signal to execute commands.

### BACKGROUND

Typically, a computer system includes a number of integrated circuit chips that communicate with one another to perform system applications. Often, the computer system includes a controller, such as a micro-processor, and one or more memory chips, such as random access memory (RAM) chips. The controller communicates with the memory to store data and to read the stored data.

The memory chips can be any suitable type of memory including RAM, which can be any suitable type of RAM, such as dynamic RAM (DRAM) including single data rate synchronous DRAM (SDR-SDRAM), double data rate SDRAM (DDR-SDRAM), graphics DDR-SDRAM (GDDR-SDRAM), low power SDR-SDRAM (LPSDR-SDRAM), and low power DDR-SDRAM (LPDDR-SDRAM). Also, the DRAM can be any suitable generation of DRAM, including double data rate two SDRAM (DDR2-SDRAM) and higher generation DRAM circuits. Usually, each new generation of DRAM operates at an increased data rate from the previous generation.

Typically, a DRAM chip includes a clock receiver that receives a clock signal to operate. Some DRAM chips receive the clock signal at a pad along the edge of the DRAM chip, referred to as an edge pad. Some DRAM chips receive the clock signal at a pad centrally located on the DRAM chip, referred to as a center pad. The clock receiver provides a clock signal in the DRAM that is used to provide multiple DRAM functions. This places multiple requirements on the clock receiver and buffer circuitry in areas such as performance, power consumption, and layout placement.

For these and other reasons there is a need for the present invention.

### SUMMARY

The present disclosure describes a memory that includes a data clock receiver and a command/address clock receiver. One embodiment provides a memory device including a memory bank, a first receiver, and a second receiver. The memory bank includes memory cells. The first receiver is configured to receive a clock signal and provide a data clock signal based on the clock signal. The second receiver is configured to receive the clock signal and provide a command/address clock signal based on the clock signal. The first receiver provides the data clock signal to output read data from the memory cells. The second receiver provides the command/address clock signal to execute commands.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a block diagram illustrating one embodiment of an integrated circuit memory, according to the present invention.

FIG. 2 is a diagram illustrating one embodiment of an integrated circuit memory that receives a differential clock signal.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “left,” “right,” “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

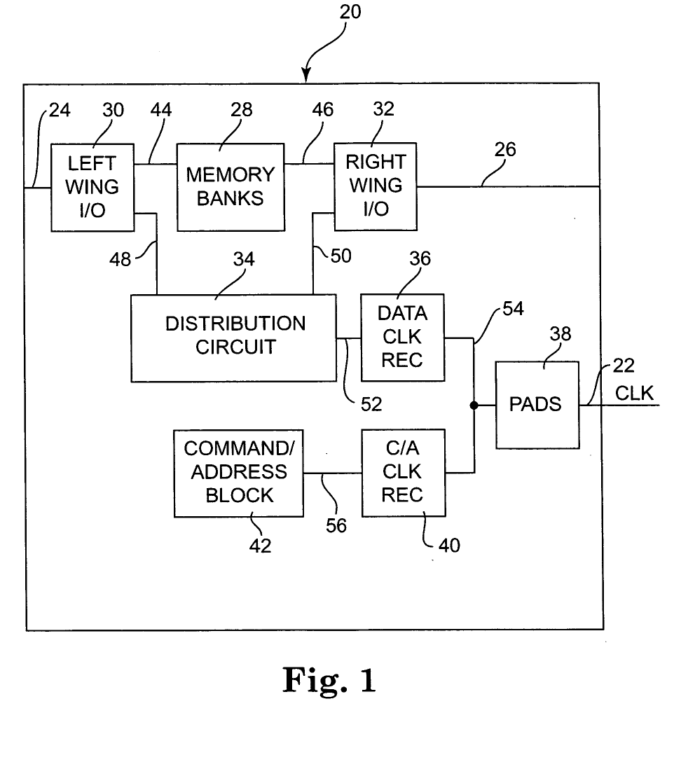

FIG. 1 is a block diagram illustrating one embodiment of an integrated circuit memory device (memory) 20, according to the present invention. In one embodiment, memory 20 is a RAM. In one embodiment, memory 20 is a DRAM, such as an SDR-SDRAM or a DDR-SDRAM. In one embodiment, memory 20 is a low power DRAM, such as a LPSDR-SDRAM or a LPDDR-SDRAM. In one embodiment, memory 20 is configured to provide either a LPSDR-SDRAM or a LPDDR-SDRAM. In other embodiments, memory 20 can be any suitable memory type or combination of memory types.

Memory 20 is electrically coupled to a package (not shown) via clock path 22, left side input/output (I/O) paths 24, and right side I/O paths 26. In a system, an external circuit, such as a controller, transfers data to and from memory 20 via left side I/O paths 24 and right side I/O paths 26. Memory 20 receives clock signal CLK at 22. In other embodiments, memory 20 receives clock signals, such as clock signal CLK at 22, on two or more sides of memory 20.

Memory 20 receives clock signal CLK at 22 and provides multiple clock signals via separate receivers. Memory 20 provides a data clock tree signal and a command/address clock signal for internal use. Each of the data clock tree signal and command/address clock signal is based on the clock signal at 22. The data clock tree signal is distributed to the left side and the right side of memory 20 to input and/or output signals via left side I/O paths 24 and right side I/O paths 26. The data clock tree signal is not provided for selected commands. The command/address clock signal is used during each of the memory commands, such as activate, read, write, and pre-charge commands. In one embodiment, the data clock tree signal is provided only during read commands. In one embodiment, the data clock tree signal is provided only during read and write commands. In other embodiments, the data clock tree signal is provided at any suitable time and during any suitable commands.

Memory 20 includes memory banks 28, a left wing I/O circuit 30, a right wing I/O circuit 32, a distribution circuit 34, a data clock receiver 36, input pads 38, a command/address clock receiver 40, and a command/address block 42. As used herein, the term “electrically coupled” is not meant to mean that the elements must be directly coupled together and intervening elements may be provided between the “electrically coupled” elements.

Memory banks 28 are electrically coupled to left wing I/O circuit 30 via left data paths 44 and to right wing I/O circuit 32 via right data paths 46. Distribution circuit 34 is electrically coupled to left wing I/O circuit 30 via left clock signal paths 48 and to right wing I/O circuit 32 via right clock signal paths 50. Also, distribution circuit 34 is electrically coupled to data clock receiver 36 via clock tree path 52. Input pads 38 are electrically coupled to data clock receiver 36 and to command/address clock receiver 40 via clock input path 54. Command/address clock receiver 40 is electrically coupled to command/address block 42 via command/address clock path 56.

Memory 20 includes multiple memory banks at 28. Each of the memory banks 28 includes memory cells, which store data in memory 20. The memory cells correspond to the memory type of memory 20. In one embodiment, each of the memory banks 28 includes RAM memory cells. In one embodiment, each of the memory banks 28 includes DRAM memory cells in a DRAM, such as an SDR-SDRAM, a DDR-SDRAM, a LPSDR-SDRAM, and/or a LPDDR-SDRAM. In one embodiment, the memory cells are in one or more arrays of memory cells. In one embodiment, memory 20 includes four memory banks. In other embodiments, memory 20 includes any suitable number of memory banks.

Left wing I/O circuit 30 receives write data from an external circuit via left side I/O paths 24 and provides the received write data to memory banks 28 for storage via left data paths 44. Left wing I/O circuit 30 receives a clock signal from distribution circuit 34 via left clock signal paths 48 and read data from memory banks 28 via left data paths 44. Left wing I/O circuit 30 provides the read data to the external circuit via left side I/O paths 24.

Right wing I/O circuit 32 receives write data from an external circuit via right side I/O paths 26 and provides the received write data to memory banks 28 for storage via right data paths 46. Right wing I/O circuit 32 receives a clock signal from distribution circuit 34 via right clock signal paths 50 and read data from memory banks 28 via right data paths 46. Right wing I/O circuit 32 provides the read data to the external circuit via right side I/O paths 26.

Input pads 38 receive clock signal CLK at 22 and provide the clock signal to data clock receiver 36 and command/address clock receiver 40 via clock input path 54. In one embodiment, clock signal CLK at 22 is a differential clock signal and input pads 38 include two input pads that receive the differential clock signal CLK at 22. In another embodiment, clock signal CLK at 22 is a single line clock signal and input pads 38 include one input pad that receives clock signal CLK at 22.

Data clock receiver 36 receives clock signal CLK at 22 and provides a data clock tree signal to distribution circuit 34 via clock tree path 52. Data clock receiver 36 is switched off and the data clock tree signal is not provided for selected commands, such as activate and pre-charge commands. In one embodiment of a LPDDR-SDRAM, data clock receiver 36 is switched on and the data clock tree signal is provided only during read commands. In one embodiment of a LPSDR-SDRAM, data clock receiver 36 is switched on and the data clock tree signal is provided only during read and write commands. In other embodiments, data clock receiver 36 is switched on and the data clock tree signal is provided at any suitable time and during any suitable commands.

Distribution circuit 34 receives the data clock tree signal and provides a distributed clock signal that is based on the data clock tree signal. The distributed clock signal is buffered and provided to left wing I/O circuit 30 via left clock signal paths 48 and to right wing I/O circuit 32 via right clock signal paths 50. Distribution circuit 34 is switched off for selected commands, such as activate and pre-charge commands. In one embodiment of a LPDDR-SDRAM, distribution circuit 34 is switched on only during read commands. In one embodiment of a LPSDR-SDRAM, distribution circuit 34 is switched on only during read and write commands. In other embodiments, distribution circuit 34 is switched on at any suitable time and during any suitable commands.

Command/address clock receiver 40 receives clock signal CLK at 22 and provides a command/address clock signal to command/address block 42 via command/address clock path 56. Command/address block 42 receives the command/address clock signal at 56 and executes each of the memory commands, such as activate, read, write, and pre-charge commands, using the command/address clock signal at 56.

Data clock receiver 36 and command/address clock receiver 40 have different functional and AC performance requirements. The data clock receiver 36 and the command/address clock receiver 40 are optimized to perform different functions. In one embodiment, the data clock receiver 36 is faster than the command/address clock receiver 40. In one embodiment, the command/address clock receiver 40 is optimized to provide set-up and hold times for the command/address block 42. In one embodiment, the data clock receiver 36 and the command/address clock receiver 40 receive different supply voltages. In one embodiment, the data clock receiver 36 and the command/address clock receiver 40 provide different output voltage levels. In one embodiment, the data clock receiver 36 and the command/address clock receiver 40 receive different input voltage levels.

In operation, data clock receiver 36 and command/address clock receiver 40 receive clock signal CLK at 22 via input pads 38. Command/address clock receiver 40 provides the command/address clock signal to command/address block 42, which executes memory commands. If data clock receiver 36 and distribution circuit 34 are switched on, data clock receiver 36 provides the data clock tree signal to distribution circuit 34 and distribution circuit 34 provides the distributed clock tree signal to left wing I/O circuit 30 and right wing I/O circuit 32. If data clock receiver 36 and distribution circuit 34 are switched off, data clock receiver 36 does not provide the data clock tree signal and power consumption is reduced.

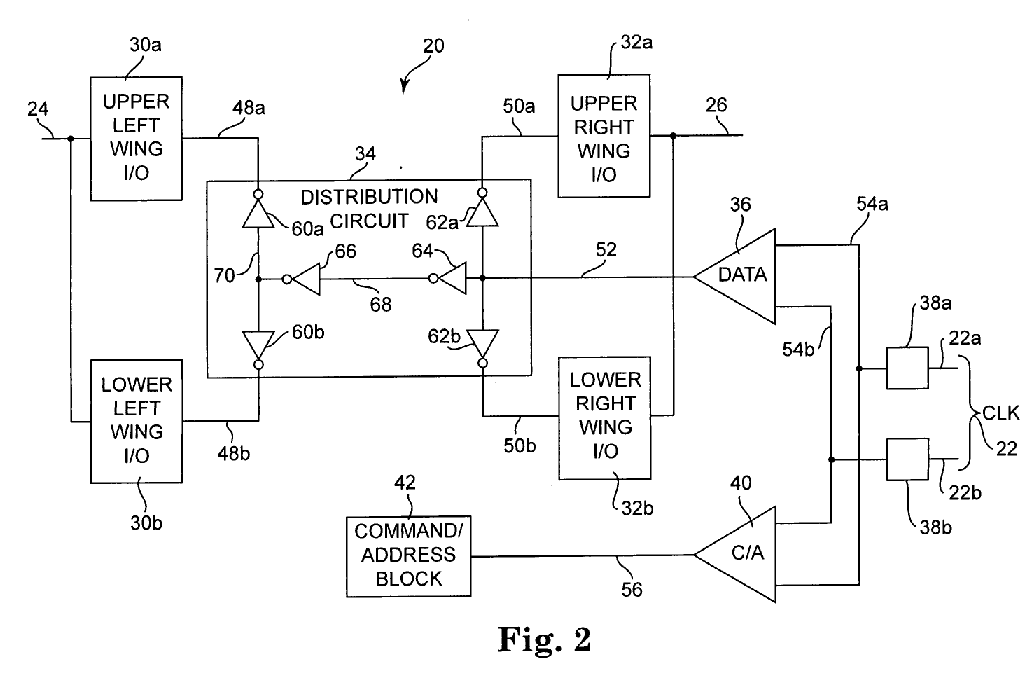

FIG. 2 is a diagram illustrating one embodiment of an integrated circuit memory 20 that receives a differential clock signal CLK at 22. Memory 20 includes an upper left wing I/O circuit 30a, a lower left wing I/O circuit 30b, an upper right wing I/O circuit 32a, a lower right wing I/O circuit 32b, distribution circuit 34, data clock receiver 36, input pads 38a and 38b, command/address clock receiver 40, and command/address block 42.

Distribution circuit 34 is electrically coupled to upper left wing I/O circuit 30a via upper left clock signal paths 48a and to lower left wing I/O circuit 30b via lower left clock signal paths 48b. Distribution circuit 34 is electrically coupled to upper right wing I/O circuit 32a via upper right clock signal paths 50a and to lower right wing I/O circuit 32b via lower right clock signal paths 50b. Distribution circuit 34 is electrically coupled to data clock receiver 36 via clock tree path 52.

Input pads 38a and 38b are electrically coupled to data clock receiver 36 and to command/address clock receiver 40 via clock input paths 54a and 54b. Input pad 38a is electrically coupled to data clock receiver 36 and to command/address clock receiver 40 via clock input path 54a. Input pad 38b is electrically coupled to data clock receiver 36 and to command/address clock receiver 40 via clock input path 54b. Command/address clock receiver 40 is electrically coupled to command/address block 42 via command/address clock path 56.

Clock signal CLK at 22 is a differential clock signal, where input pad 38a receives one side of the differential clock signal via clock input path 22a and input pad 38b receives the other side of the differential clock signal via clock input path 22b. Input pads 38a and 38b receive clock signal CLK at 22a and 22b, respectively, and provide clock signal CLK to data clock receiver 36 and command/address clock receiver 40 via clock input paths 54a and 54b. Data clock receiver 36 receives the differential clock signal CLK and provides a data clock tree signal at 52 to distribution circuit 34 via clock tree path 52. Command/address clock receiver 40 receives the differential clock signal CLK and provides a command/address clock signal at 56 to command/address block 42 via command/address clock path 56.

Distribution circuit 34 includes an upper left buffer circuit 60a, a lower left buffer circuit 60b, an upper right buffer circuit 62a, a lower right buffer circuit 62b, a clock signal distribution buffer 64, and a left clock tree buffer 66. Each of the buffers, including upper left buffer circuit 60a, lower left buffer circuit 60b, upper right buffer circuit 62a, lower right buffer circuit 62b, distribution buffer 64, and left clock tree buffer 66, is an inverting buffer. In other embodiments, each of the buffers can be any suitable type of buffer, such as an inverting buffer or a non-inverting buffer.

The output of data clock receiver 36 is electrically coupled to the inputs of upper right buffer circuit 62a, lower right buffer circuit 62b, and distribution buffer 64 via clock tree path 52. The output of distribution buffer 64 is electrically coupled to the input of left clock tree buffer 66 via distribution path 68. The output of left clock tree buffer 66 is electrically coupled to the inputs of upper left buffer circuit 60a and lower left buffer circuit 60b via left clock tree path 70.

Upper left buffer circuit 60a is electrically coupled to upper left wing I/O circuit 30a via upper left clock signal paths 48a. Lower left buffer circuit 60b is electrically coupled to lower left wing I/O circuit 30b via lower left clock signal paths 48b. Upper right buffer circuit 62a is electrically coupled to upper right wing I/O circuit 32a via upper right clock signal paths 50a. Lower right buffer circuit 62b is electrically coupled to lower right wing I/O circuit 32b via lower right clock signal paths 50b.

Distribution circuit 34 receives the data clock tree signal at 52 and provides a distributed clock signal that is based on the data clock tree signal at 52 to upper left wing I/O circuit 30a, lower left wing I/O circuit 30b, upper right wing I/O circuit 32a, and lower right wing I/O circuit 32b.

Upper right buffer circuit 62a, lower right buffer circuit 62b, and distribution buffer 64 receive the data clock tree signal at 52. Upper right buffer circuit 62a provides an upper right distributed clock signal at 50a to upper right wing I/O circuit 32a. Lower right buffer circuit 62b provides a lower right distributed clock signal at 50b to lower right wing I/O circuit 32b. Distribution buffer 64 provides a distributed clock signal at 68 to left clock tree buffer 66.

Left clock tree buffer 66 receives the distributed clock signal at 68 and provides a left clock tree signal at 70 to upper left buffer circuit 60a and lower left buffer circuit 60b via left clock tree path 70. Upper left buffer circuit 60a and lower left buffer circuit 60b receive the left clock tree signal at 70. Upper left buffer circuit 60a provides an upper left distributed clock signal at 48a to upper left wing I/O circuit 30a. Lower left buffer circuit 60b provides a lower left distributed clock signal at 48b to lower left wing I/O circuit 30b.

Upper left wing I/O circuit 30a receives the upper left distributed clock signal at 48a from upper left buffer circuit 60a via upper left clock signal paths 48a and read data from the memory banks (FIG. 1). Upper left wing I/O circuit 30a provides the read data to the external circuit via left side I/O paths 24. Also, upper left wing I/O circuit 30a receives write data from an external circuit via left side I/O paths 24 and provides the received write data to memory banks for storage.

Lower left wing I/O circuit 30b receives the lower left distributed clock signal at 48b from lower left buffer circuit 60b via lower left clock signal paths 48b and read data from the memory banks. Lower left wing I/O circuit 30b provides the read data to the external circuit via left side I/O paths 24. Also, lower left wing I/O circuit 30b receives write data from an external circuit via left side I/O paths 24 and provides the received write data to memory banks for storage.

Upper right wing I/O circuit 32a receives the upper right distributed clock signal at 50a from upper right buffer circuit 62a via upper right clock signal paths 50a and read data from the memory banks. Upper right wing I/O circuit 32a provides the read data to the external circuit via right side I/O paths 26. Also, upper right wing I/O circuit 32a receives write data from an external circuit via right side I/O paths 26 and provides the received write data to memory banks for storage.

Lower right wing I/O circuit 32b receives the lower right distributed clock signal at 50b from lower right buffer circuit 62b via lower right clock signal paths 50b and read data from the memory banks. Lower right wing I/O circuit 32b provides the read data to the external circuit via right side I/O paths 26. Also, lower right wing I/O circuit 32b receives write data from an external circuit via right side I/O paths 26 and provides the received write data to memory banks for storage.

In operation, input pads 38a and 38b receive differential clock signal CLK at 22a and 22b, respectively. Input pads 38a and 38b provide clock signal CLK to data clock receiver 36 and command/address clock receiver 40. Command/address clock receiver 40 receives the differential clock signal CLK and provides the command/address clock signal at 56 to command/address block 42, which executes memory commands. Data clock receiver 36 receives the differential clock signal CLK.

If data clock receiver 36 is switched on, data clock receiver 36 provides the data clock tree signal at 52 to distribution circuit 34. If distribution circuit 34 is switched on, distribution circuit 34 receives the data clock tree signal at 52 and provides a distributed clock signal to upper left wing I/O circuit 30a, lower left wing I/O circuit 30b, upper left wing I/O circuit 32a, and lower left wing I/O circuit 32b. If data clock receiver 36 and distribution circuit 34 are switched off, data clock receiver 36 does not provide the data clock tree signal at 52 and power consumption is reduced.

If data clock receiver 36 and distribution circuit 34 are switched on, upper left buffer circuit 60a receives the left clock tree signal at 70 and provides the upper left distributed clock signal at 48a to upper left wing I/O circuit 30a. Lower left buffer circuit 60b receives the left clock tree signal at 70 and provides the lower left distributed clock signal at 48b to lower left wing I/O circuit 30b. Also, upper right buffer circuit 62a receives the data clock tree signal at 52 and provides the upper right distributed clock signal at 50a to upper right wing I/O circuit 32a. Lower right buffer circuit 62b receives the data clock tree signal at 52 and provides the lower right distributed clock signal at 50b to lower right wing I/O circuit 32b.

Memory 20 includes a data clock receiver 36 and a command/address clock receiver 40. Each of these receivers can be built to optimize their performance in their respective functions. Also, the data clock receiver 36 and command/address clock receiver 40 can be situated on an integrated circuit chip to optimize performance. In addition, the data clock receiver 36 can be switched off to reduce power consumption for selected commands and/or when not in use.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory device, comprising:
a memory bank including memory cells;
a first receiver configured to receive a clock signal and provide a data clock signal based on the clock signal; and
a second receiver configured to receive the clock signal and provide a command/address clock signal based on the clock signal, wherein the first receiver provides the data clock signal to output read data from the memory cells and the second receiver provides the command/address clock signal to execute commands.

2. The memory device of claim 1, comprising:
two input pads, wherein the clock signal is a differential clock signal received by the first receiver and the second receiver via the two input pads.

3. The memory device of claim 1, wherein the first receiver is configured to be powered down during execution of selected commands.

4. The memory device of claim 1, wherein the first receiver is configured to be powered up only during read operations.

5. The memory device of claim 1, wherein the first receiver is configured to be powered up only during read and write operations.

6. The memory device of claim 1, wherein the first receiver is configured to operate at higher frequencies than the second receiver.

7. The memory device of claim 1, wherein the first receiver is configured to operate at different supply voltages than the second receiver.

8. The memory device of claim 1, wherein the first receiver is configured to operate with at least one of different input voltage levels and different output voltage levels than the second receiver.

9. A random access memory, comprising:
a memory bank including random access memory cells;
a first receiver configured to receive a clock signal and provide a data clock signal based on the clock signal;
a second receiver configured to receive the clock signal and provide a command/address clock signal based on the clock signal;
a first circuit configured to receive the data clock signal and output read data from the random access memory cells; and
a second circuit configured to receive the command/address clock signal and execute commands.

10. The random access memory of claim 9, wherein the random access memory comprises:
a single data rate synchronous dynamic random access memory.

11. The random access memory of claim 9, wherein the random access memory comprises:
a double data rate synchronous dynamic random access memory.

12. The random access memory of claim 9, comprising:
two input pads, wherein the clock signal comprises a differential clock signal received by the first receiver and the second receiver via the two input pads.

13. The random access memory of claim 9, wherein the first receiver is configured to be powered down during execution of selected commands.

14. A random access memory, comprising:
means for storing data;
means for receiving a clock signal;
means for providing a data clock signal based on the clock signal; and
means for providing a command/address clock signal based on the clock signal.

15. The random access memory of claim 14, comprising:
means for outputting read data from the means for storing data based on the data clock signal; and
means for executing commands based on the command/address clock signal.

16. The random access memory of claim 14, wherein the means for receiving a clock signal comprises two input pads.

17. The random access memory of claim 14, wherein the means for providing a data clock signal based on the clock signal is configured to power down during execution of selected commands.

18. The random access memory of claim 14, comprising:
means for distributing the data clock signal to at least two sides of the random access memory.

19. A method of clocking in a memory, comprising:
receiving a clock signal at a first receiver and a second receiver;
providing a data clock signal based on the clock signal via the first receiver; and
providing a command/address clock signal based on the clock signal via the second receiver.

20. The method of claim 19, comprising:
outputting read data from memory cells based on the data clock signal; and
executing commands based on the command/address clock signal.

21. The method of claim 19, comprising:
powering down the first receiver during execution of selected commands.

22. The method of claim 19, comprising:
powering up the first receiver only during execution of read commands.

23. The method of claim 19, comprising:
powering up the first receiver only during execution of read and write commands.

24. The method of claim 19, comprising:
distributing the data clock signal to at least two sides of the memory.

25. A method of clocking in a random access memory, comprising:
receiving a clock signal;
providing a data clock signal based on the clock signal via a first receiver;
providing a command/address clock signal based on the clock signal via a second receiver;
outputting read data from random access memory cells based on the data clock signal; and
executing commands based on the command/address clock signal.

26. The method of claim 25, comprising:
powering down the first receiver during execution of selected commands.

27. The method of claim 25, wherein receiving a clock signal comprises:
receiving a differential clock signal via two input pads.

28. A system, comprising:
an external circuit; and
a memory device configured to transfer data to and receive data from the external circuit, the memory device including:
a memory bank including memory cells;
a first receiver configured to receive a clock signal and provide a data clock signal based on the clock signal; and
a second receiver configured to receive the clock signal and provide a command/address clock signal based on the clock signal, wherein the first receiver provides the data clock signal to output read data from the memory cells and the second receiver provides the command/address clock signal to execute commands.

29. The system of claim 28, wherein the first receiver is configured to be powered down during execution of selected commands.

30. The system of claim 28, wherein the first receiver is configured to be powered up only during read operations.

31. The system of claim 28, wherein the first receiver is configured to be powered up only during read and write operations.
